(19) United States
(12) Patent Application Publication
(10) Pub. No.: US 2014/0217555 A1
(43) Pub. Date: Aug. 7, 2014

(54) SEMICONDUCTOR DEVICE AND MANUFACTURING METHOD THEREOF

(71) Applicant: Kabushiki Kaisha Toshiba, Minato-ku (JP)

(72) Inventor: Ryota OHNUKI, Yokkaichi-shi (JP)

(73) Assignee: Kabushiki Kaisha Toshiba, Minato-ku (JP)

(21) Appl. No.: 13/905,317

(22) Filed: May 30, 2013

Related U.S. Application Data
(60) Provisional application No. 61/761,275, filed on Feb. 6, 2013.

(51) Int. Cl. H01L 29/02; H01L 21/306

(52) U.S. Cl. CPC H01L 29/02; H01L 21/306
USPC 257/618; 438/694

(57) ABSTRACT

A semiconductor device according to the present embodiment includes a semiconductor substrate. A plurality of line patterns are formed into stripes present above the semiconductor substrate. Each of the line patterns includes a narrow portion having a constricted width in a perpendicular direction to an extension direction of the line pattern.

### CROSS REFERENCE TO RELATED APPLICATIONS

This application is based upon and claims the benefit of priority from the prior U.S. patent application Ser. No. 61/761,275, filed on Feb. 6, 2013 the entire contents of which are incorporated herein by reference.

### FIELD

The embodiments of the present invention relate to a ,semiconductor device and a manufacturing method thereof.

### BACKGROUND

In recent years, the line width and the space width of line-and-space have become narrower to follow the downscaling of semiconductor devices. For example, the line width and the space width of control gates (that is, word lines) of a NAND flash EEPROM (Electrically Erasable Programmable Read-Only Memory) have become narrower to follow the downscaling. When such narrow-width line-and-space is formed, a ground material may deposit on the side surfaces of lines as an etching residue on ends of the lines. The etching residue increases the line width and reduces the space width from a designed line width and a designed space width, respectively. That is, the etching residue increases a process conversion difference on the ends of the lines. In this case, for example, a breakdown voltage may be possibly reduced between the adjacent word lines or a short-circuit may occur between the adjacent word lines.

### BRIEF DESCRIPTION OF THE DRAWINGS

FIG. 1 is a configuration diagram of a memory cell array MCA of a NAND flash EEPROM according to a first embodiment;

FIG. 2 is a cross-sectional view showing a configuration of the memory cells MC in the NAND flash EEPROM according to the first embodiment;

FIG. 3 shows a structure of ends of the word lines WL according to the first embodiment;

FIGS. 4 to 12 are cross-sectional views showing a manufacturing method of the NAND flash EEPROM according to the first embodiment;

FIGS. 13A to 16B are cross-sectional views and plan views showing steps of processing the control gates CG according to the first embodiment;

FIG. 17 shows a structure of ends of the word lines WL according to a second embodiment; and

FIGS. 18A to 21B are cross-sectional views and plan views showing steps of processing the control gates CG according to the second embodiment.

### DETAILED DESCRIPTION

A semiconductor device according to the present embodiment includes a semiconductor substrate. A plurality of line patterns are formed into stripes present above the semiconductor substrate. Each of the line patterns includes a narrow portion having a constricted width in a perpendicular direction to an extension direction of the line pattern.

Embodiments will now be explained with reference to the accompanying drawings. The present invention is not limited to the embodiments.

In the following explanations, a term referring to a direction such as an upper direction or a lower direction indicates a relative direction when a surface of a semiconductor substrate on which semiconductor elements are provided is assumed as “upper surface”. Accordingly, the upper direction or the lower direction may differ from a vertical direction based on a gravitational acceleration direction.

### First Embodiment

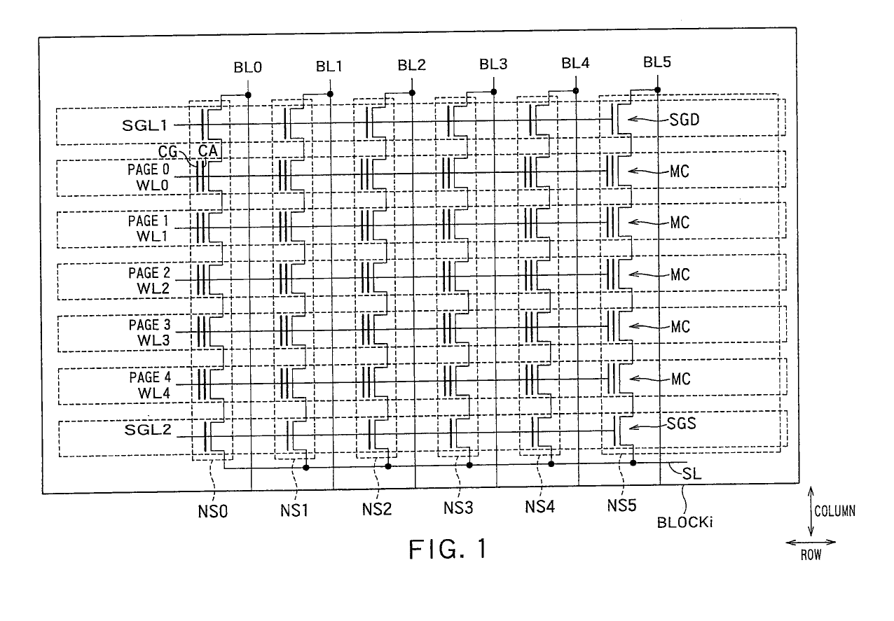

FIG. 1 is a configuration diagram of a memory cell array MCA of a NAND flash EEPROM according to a first embodiment. A semiconductor device is described below while referring to the NAND flash EEPROM as an example. The memory cell array includes a plurality of memory blocks BLOCK. FIG. 1 shows a configuration of a certain block BLOCKi (where i is an integer). The block BLOCKi is a data erase unit and includes a plurality of NAND strings NS0 to NS5 connected to bit lines BL in respective columns. Each of the NAND strings NS0 to NS5 includes a plurality of memory cells MC connected in series and selection gate transistors SGS and SGD connected to both ends of a group of these memory cells MC. The NAND strings NS are provided on an active area AA formed into stripes. In an example shown in FIG. 1, five memory cells MC are connected in series per NAND string NS. Generally, 32 or 64 memory cells MC are connected in series per NAND string NS. One end of each of the NAND strings NS0 to NS5 is connected to corresponding one of the bit lines BL0 to BLS, and the other end thereof is connected to a common source line SL.

Control gates CG of the memory cells MC are connected to word lines WL0 to WL4 corresponding to pages to which the memory cells MC belong, respectively. Alternatively, the control gates CG and the word lines WL0 to WL4 can be formed integrally and the control gates CG can function as the word lines WL0 to WL4, respectively. For example, the control gates CG of the memory cells MC belonging to a page j (j=0 to 4) are connected to a word line WLj. Gates of the selection gate transistors SGD and SGS are connected to a selection gate line SGL1 or SGL2. The page is a data read unit or a data write unit.

The control gates CG are explained below while assuming that the control gates CG also function as the word lines WL. A plurality of control gates CG (that is, world lines WL) extend in a row direction and are formed into stripes in line-and-space patterns. A plurality of bit lines BL extend in a column direction so as to be substantially orthogonal to the row direction.

As shown in FIG. 1, the memory cells MC are provided to correspond to grid intersections constituted by the word lines WL and the bit lines BL, respectively. For example, the grid intersections constituted by the word lines WL0 to WL4 and the bit lines BL0 to BL5 are located in a 5×6 matrix. The memory cells MC are arranged two-dimensionally in a 5×6 matrix so as to correspond to these intersections, respectively. While the block BLOCKi of the memory cells MC includes 5×6 (=30) memory cells MC, the number of memory cells MC per block BLOCKi is not limited to 5×6.

Each of the memory cells MC is constituted by an n-FET (Field-Effect Transistor) that includes a charge accumulation layer CA and one control gate CG. By allowing one word line WL to apply a voltage to the control gate CG, electric charges (electrons) are injected into or discharged from the charge accumulation layer CA. Data is thereby written to or erased from each memory cell MC. The memory cell MC has a threshold voltage according to a quantity of electric charges (the number of electrons) accumulated in the charge accumulation layer CA. The memory cell MC can electrically store binary data (one bit) or multilevel data (two or more bits) depending on the threshold voltage.

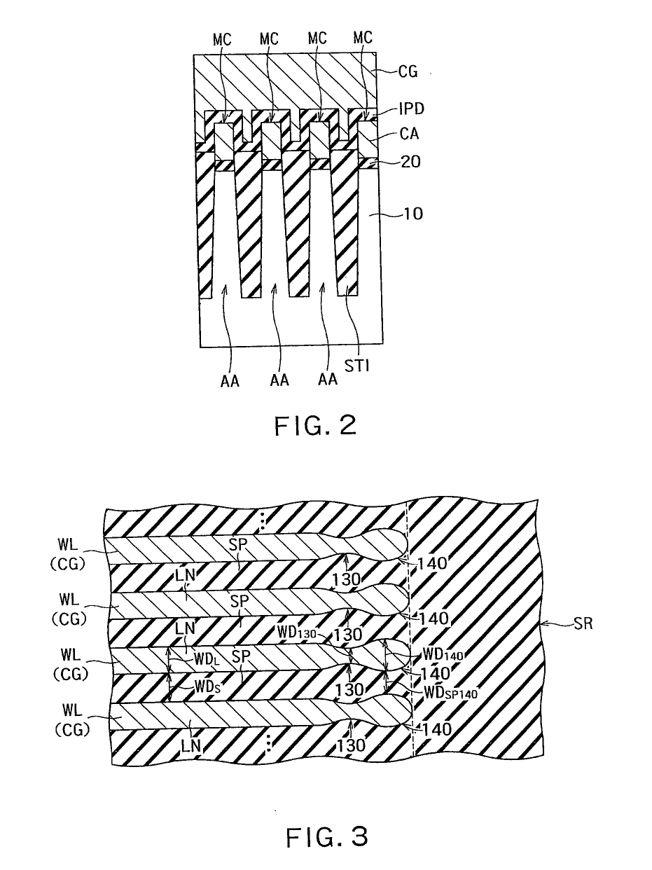

FIG. 2 is a cross-sectional view showing a configuration of the memory cells MC in the NAND flash EEPROM according to the first embodiment. Each of the memory cells MC is formed on a semiconductor substrate 10 and includes a tunnel gate dielectric film 20, the charge accumulation layer CA, an inter-gate dielectric film IPD, and the control gate CG.

The tunnel gate dielectric film 20 is provided on the semiconductor substrate 10. The tunnel gate dielectric film 20 is formed by using a silicon oxide film, for example. The charge accumulation layer CA is provided on the tunnel gate dielectric film 20, and can store data by either accumulating electric charges (electrons) therein or discharging the electric charges therefrom. The charge accumulation layer CA is formed by using polysilicon, for example. The inter-gate dielectric film IPD is provided on the charge accumulation layer CA. The inter-gate dielectric film IPD is formed by using, for example, a silicon oxide film, a silicon nitride film, or a High-k film higher in dielectric constant than the silicon oxide film. The control gate CG is provided on the inter-gate dielectric film IPD and controls a voltage of the charge accumulation layer CA. The control gate CG is formed by using polysilicon, for example.

The control gate CG and the inter-gate dielectric film IPD are made to fall into an element isolation STI (the semiconductor substrate 10) between the two adjacent memory cells MC, and face two side surfaces of the charge accumulation layers CA in the row direction. This increases a coupling capacitance ratio between a channel and the charge accumulation layer CA or between the control gate CG and the charge accumulation layer CA, and the control gate CG can easily control the voltage of the charge accumulation layer CA.

FIG. 3 shows a structure of ends of the word lines WL (the control gates CG) according to the first embodiment. As shown in FIG. 2, the word lines WL are formed above the semiconductor substrate 10 and formed into stripes in line-and-space patterns.

Line patterns of the word lines WL are formed so that each line has a line width WD_{L}, and space patterns SP between the adjacent word lines WL are formed so that each space has a space width WD_{S}. Both of the line width WD_{L} and the space width WD_{S} are widths in a perpendicular direction to an extension direction of the word lines WL in the line-and-space patterns.

Each of the line patterns of the word lines WL includes a narrow portion (constricted portion) 130 and a wide portion (expanded portion) 140 on the respective ends. A width WD₁₃₀ of the narrow portion 130 (a width in the perpendicular direction to the extension direction of the line pattern of each word line WL) is constricted and narrower than the line width WD_{L} of a central portion of the line pattern.

On the other hand, a width WD₁₄₀ of the wide portion 140 (a width in the perpendicular direction to the extension direction of the line pattern of each word line WL) is formed to be wider than the width WD₁₃₀ of the narrow portion 130. The width WD₁₄₀ of the wide portion 140 suffices to be equal to or different to some extent from the line width WD_{L} of the central portion of the line pattern.

Each of the line patterns of the word lines WL has the substantially uniform line width WD_{L} in the central portion (inside) of the line pattern. However, from the central portion to the end of the line pattern, the line width of the word line WL is once reduced and constricted in the narrow portion 130 but is increased again in the wide portion 140 nearer a tip end than the narrow portion 130.

The wide portion 140 is adjacent to a space region SR where no word lines WL are formed. When the word lines WL are etched, a material layer (a line-pattern material layer) of the word lines WL is entirely removed in the space region SR. For example, in a case of forming the line patterns of the word lines WL using RIE (Reactive Ion Etching), the line-pattern material layer in the space region SR is entirely etched. At this time, the line-pattern material layer in the space region SR may sometimes re-adhere on the ends of the line patterns of the word lines WL as the etching residue. In such a case, the width of the end of the line pattern of each word line WL is formed to be wider than the line width WD_{L} of the central portion. That is, the line width of the end of the line pattern is wider (larger) than a designed and expected line width, resulting in an increase in the process conversion difference. This conversely means a reduction in the space width on the end of the line pattern. Therefore, this possibly reduces the breakdown voltage between the adjacent word lines WL and causes a short-circuit between the adjacent word lines WL.

On the other hand, the line pattern of each word line WL according to the first embodiment includes the narrow portion 130 on the end thereof. That Is, the width WD₁₃₀ of the end of the line pattern of each word line WL is formed to be narrower (thinner) than the line width WD_{L} of the central portion. Therefore, even when the etching residue re-adheres on the end of the line pattern of each word line WL, it is possible to suppress the width WD₁₄₀ of the end of the line pattern from becoming excessively wider (larger) than a designed width. That is, the first embodiment can reduce the process conversion difference. As a result, the memory according to the first embodiment can keep the breakdown voltage between the adjacent word lines WL and suppress the short-circuit between the adjacent word lines WL without greatly narrowing a space width WD_{SP140} on the end of each line pattern.

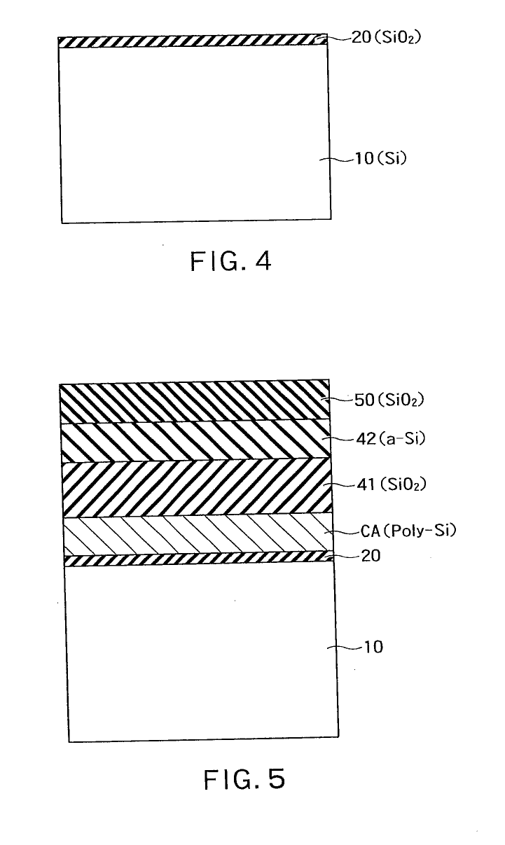

FIGS. 4 to 12 are cross-sectional views showing a manufacturing method of the NAND flash EEPROM according to the first embodiment. First, as shown in FIG. 4, the tunnel gate dielectric film 20 serving as a first insulating film and a gate dielectric film 30 serving as a second insulating film are formed on the semiconductor substrate 10. The tunnel gate dielectric film 20 is formed by using, for example, a silicon oxide film formed by thermally oxidizing the semiconductor substrate 10.

Next, as shown in FIG. 5, the material of the charge accumulation layer CA is deposited on the tunnel gate dielectric film 20 and the gate dielectric film 30. The charge accumulation layer CA is formed by using polysilicon, for example.

Next, the material of a first mask material 41, the material of a second mask material 42, and the material of a mandrel 50 are deposited on the material of the charge accumulation layer CA. The first mask material 41 is formed by using, for example, an insulating film such as a silicon oxide film. The second mask material 42 is formed by using, for example, an insulating film such as an amorphous silicon film or a silicon nitride film different from the insulating films for forming the first mask material 41 and the mandrel 50. The mandrel 50 is formed by using, for example, an insulating film such as a silicon oxide film. The material of the mandrel 50 is then processed using a lithographic technique and a RIE method.

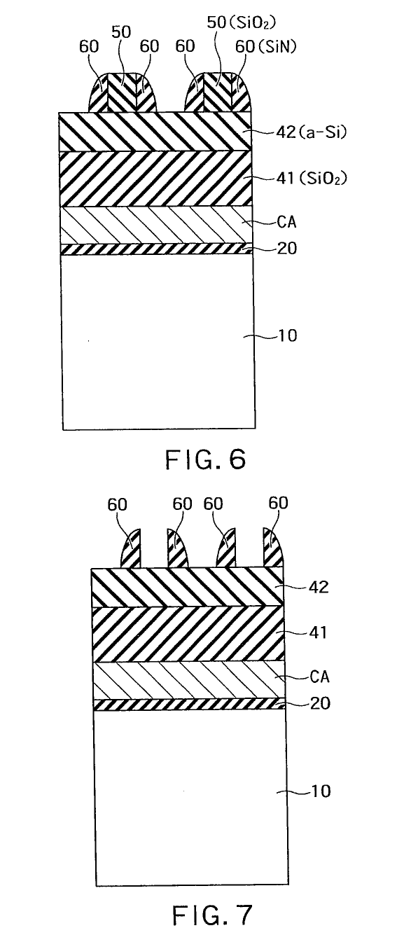

The material of a sidewall mask 60 is then deposited on upper and side surfaces of the mandrel 50 and on the material of the second mask material 42. The material of the sidewall mask 60 is formed by using, for example, an insulating film such as a silicon nitride film or an amorphous silicon film different from the insulating film for forming the mandrel 50. Using the RIE method, the material of the sidewall mask 60 is then anisotropically etched back. Accordingly, the sidewall mask 60 remains on the side surface of the mandrel 50 as shown in FIG. 6.

The exposed mandrel 50 is then selectively etched while having the sidewall mask 60 remained thereon. At this time, the mandrel 50 is removed by isotropic etching such as wet etching and CDE (Chemical Dry Etching). Accordingly, the sidewall mask 60 is formed into patterns of the charge accumulation layers CA as shown in FIG. 7.

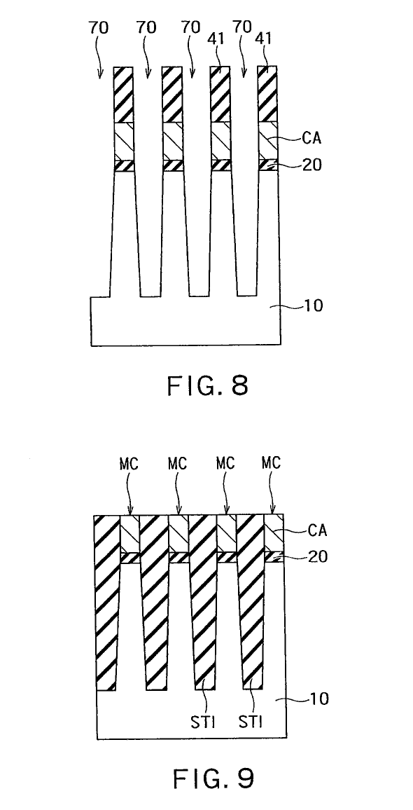

Next, using the sidewall mask 60 or the mandrel 50 as a mask, the second mask material 42 is processed by the RIE method. Using the second mask material 42 as a mask, the first mask material 41 is processed by the RIE method. Using the first mask material 41 as a mask, the material of the charge accumulation layer CA, the tunnel gate dielectric film 20, the gate dielectric film 30, and the semiconductor substrate 10 are processed by the RIE method. As a result, the charge accumulation layers CA are formed and trenches 70 used for the element isolation STI are formed as shown in FIG. 8.

An element-isolation dielectric film 80 is then filled in the trenches 70. The element-isolation dielectric film 80 is then planarized until upper surfaces of the charge accumulation layers CA are exposed. As a result, a structure shown in FIG. 9 is obtained.

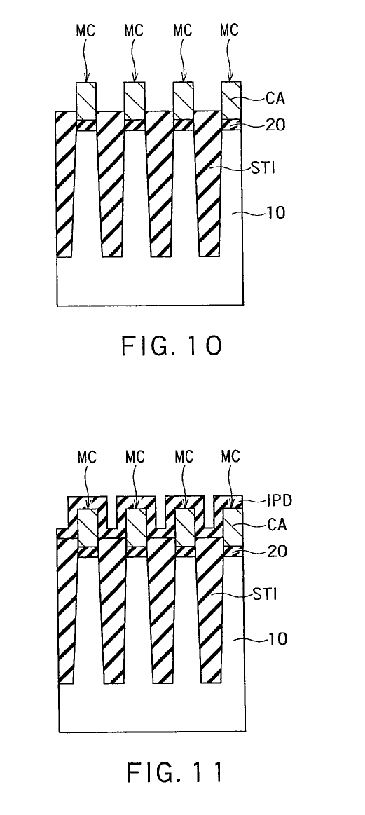

Next, as shown in FIG. 10, the element-isolation dielectric film 80 present in the memory cell array MCA is etched back, thereby exposing upper portions of the side surfaces of the charge accumulation layers CA.

Next, as shown in FIG. 11, the inter-gate dielectric film IPD is deposited on the upper and side surfaces of the charge accumulation layers CA of the memory cells MC and a first dummy cell DC1, respectively. That is, the inter-gate dielectric film IPD is made to fall into the element isolation STI (the semiconductor substrate 10) between the two adjacent memory cells MC.

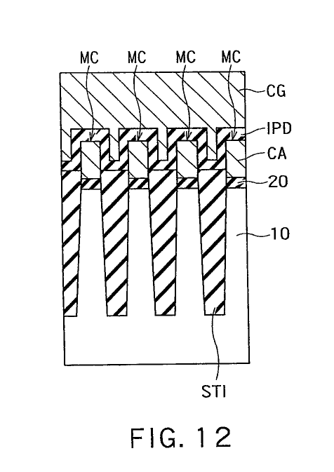

Next, as shown in FIG. 12, the material of the control gates CG serving as the line-pattern material layer is deposited on the inter-gate dielectric film IPD. The material of the control gates CG is formed by using polysilicon or metal silicide, for example. The material of the control gates CG faces the upper and side surfaces of the charge accumulation layers CA of the memory cells MC via the inter-gate dielectric film IPD, respectively.

The control gates CG are processed next.

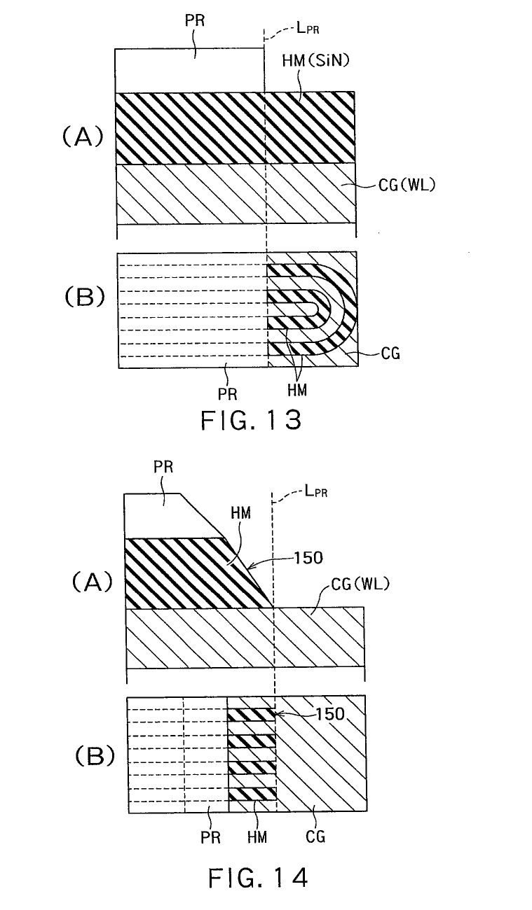

FIGS. 13A to 16B are cross-sectional views and plan views showing processing steps of the control gates CG according to the first embodiment. FIGS. 13A to 16A are cross-sectional views and FIGS. 13B to 16B are plan views.

The material of a hard mask HM is deposited on the material of the control gates CG (the word lines WL). The hard mask HM is formed by using a silicon nitride film, for example. Using the lithographic technique and the RIE method, the hard mask HM is processed into the line patterns of the word lines WL. At this time, as shown in FIG. 13B, ends of the line patterns of the hard mask HM are formed into a loop so as to connect a plurality of line patterns.

Next, as shown in FIGS. 13A and 13B, the line patterns of the hard mask HM are covered with a photoresist PR and the ends of the line patterns of the hard mask HM are exposed. That is, an end region of the hard mask HM formed into a loop is opened (exposed) whereas regions of the line patterns other than the end region of the hard mask HM are covered with the photoresist PR. Reference character L_{PR} denotes an initial position of one end of the photoresist PR.

Next, using the photoresist PR as a mask, the hard mask HM is etched by the RIE method. Accordingly, the end of the hard mask HM formed into a loop is removed, and the hard mask HM is processed into a plurality of line patterns (loop cut) as shown in FIG. 14B.

At this time, gas having a relatively high oxygen content is used as etching gas. For example, gas containing CxHyFz (where x, y, and z are positive numbers) and oxygen can be used as the etching gas. Specifically, for example, CF₄ and O₂ gas can be used as the etching gas. The etching gas having a high oxygen content is capable of etching the hard mask HM while retracting a side surface of the photoresist PR from the position L_{PR}. By etching the hard mask HM while retracting the side surface of the photoresist PR, an end surface 150 of the hard mask HM is processed to be forward tapered shape as shown in FIG. 14A.

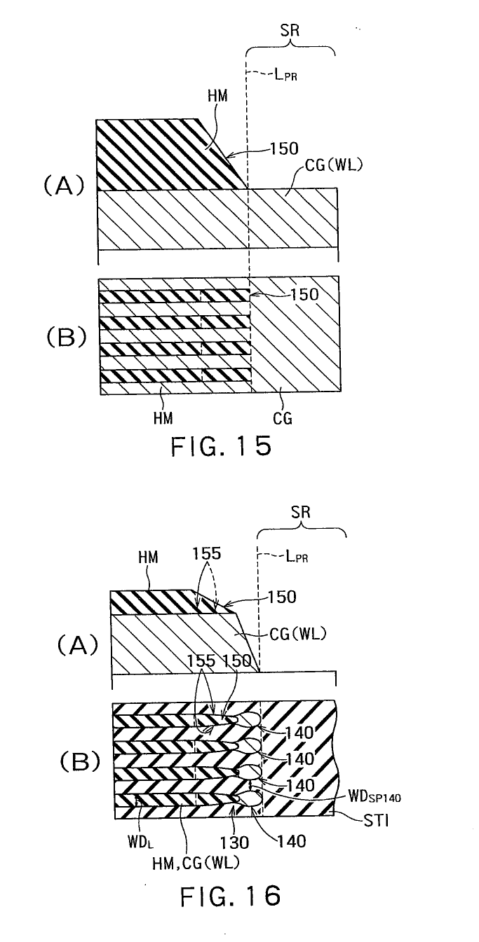

Next, as shown in FIGS. 15A and 15B, the photoresist PR is removed.

Next, using the hard mask HM having the tapered end surface 150 as a mask, the material of the control gates CG (the line-pattern material layer) is etched by the RIE method. At this time, the hard mask HM is also etched to some extent. The etching of the hard mask HM starts not only from the end surface 150 but also from a side surface 155 of the end. Therefore, the material of the control gates CG is processed into a tapered shape because the hard mask HM has the tapered end surface 150.

On the other hand, in the space region SR where no line patterns are formed, the material (polysilicon, for example) of the control gates CG is etched in large amounts. Therefore, the etching residue deposits on tip ends of the line patterns of the respective control gates CG. As shown in FIG. 16B, the etching residue forms the wide portions 140 on the tip ends of the respective line patterns. As described above, the material of the control gates CG is formed into the tapered shape. Accordingly, by forming the wide portion 140 on the tip end of each of the line patterns, the narrow portion 130 and the wide portion 140 are formed on the line pattern of each control gate CG. In this way, at the time of processing the control gates CG, the line patterns are formed and the narrow portion 130 and the wide portion 140 are formed on the end of each line pattern.

As described above, the narrow portion 130 is a portion having the constricted width in the perpendicular direction to the extension direction of the line pattern of each control gate CG. The wide portion 140 is the portion once made wider than that of the narrow portion 130 of the line pattern in the width in the perpendicular direction to the extension direction of the line pattern of the control gate CG on the tip end of the line pattern.

Thereafter, an interlayer dielectric film, the bit lines BL, and the like are formed, thereby completing the NAND flash EEPROM according to the first embodiment.

In this way, according to the first embodiment, the word lines WL are processed using the hard mask HM having a tapered shape on the end thereof. The line pattern of each word line WL is thereby formed to have the narrow portion 130 and the wide portion 140 on the end. That is, the line pattern of the word line WL is formed so as to be constricted once in the narrow portion 130 on the end of the line pattern while having the substantially uniform line width WD_{L} in the central portion of the line pattern, and so as to be widened in the wide portion 140 nearer the tip end than the narrow portion 130. Because the wide portion 140 is formed on the tip end of the word line WL processed to be tapered, the width WD₁₄₀ of the wide portion 140 does not so differ from the line width WD_{L}. Therefore, it is possible to maintain a sufficient space width WD_{SP140} between the adjacent wide portions 140. As a result, according to the first embodiment, it is possible to keep the breakdown voltage between the adjacent word lines WL and to suppress the short-circuit between the adjacent word lines WL.

### Second Embodiment

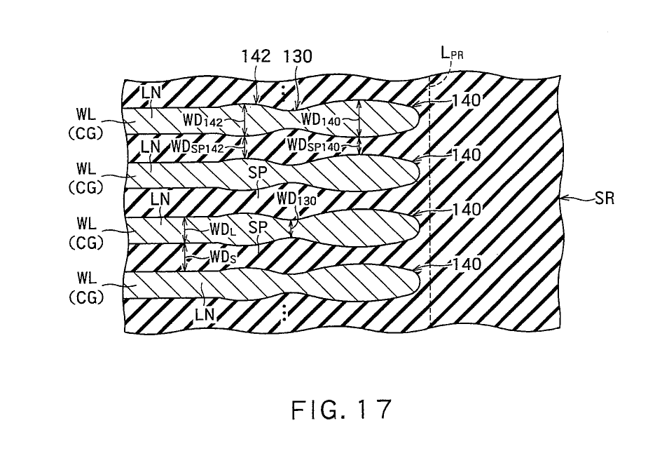

FIG. 17 shows a structure of ends of the word lines WL (the control gates CG) according to a second embodiment, The second embodiment differs from the first embodiment in that the line pattern of each of the word lines WL has not only the wide portion (first wide portion) 140 but also a second wide portion 142. The second wide portion 142 is located nearer a center side of the line pattern of the word line WL than the narrow portion 130. The second wide portion 142 is formed to be wider than the narrow portion 130 in a width in the perpendicular direction to the extension direction of the line pattern. In the second embodiment, the narrow portion 130 is formed between the first wide portion 140 and the second wide portion 142. Other configurations of the second embodiment can be identical to the corresponding ones of the first embodiment.

As described later, in the second embodiment, the material of the word lines WL (the line-pattern material layer) is processed by using the hard mask HM having a stepped portion. Using this stepped portion, the first and second wide portions 140 and 142 and the narrow portions 130 are formed. Reference characters WD₁₄₀ and WD₁₄₂ denote line widths of the first and second wide portions 140 and 142, respectively. Reference characters WD_{SP140} and WD_{SP142} denote a space width between the adjacent first wide portions 140 and that between the adjacent second wide portions 142, respectively. Reference character WD₁₃₀ denotes the width of each narrow portion 130.

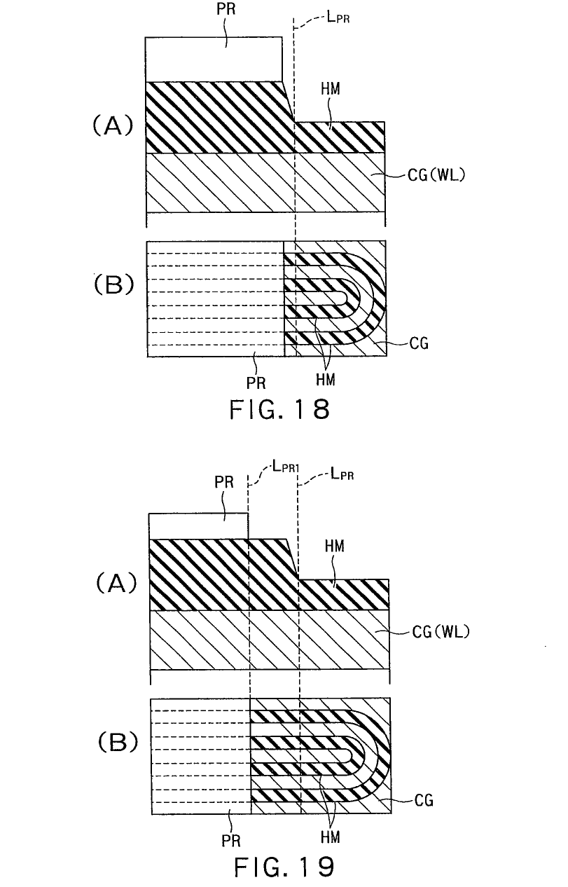

FIGS. 18A to 20B are cross-sectional views and plan views showing steps of processing the control gates CG according to the second embodiment. FIGS. 18A to 20A are cross-sectional views and FIGS. 18B to 20B are plan views.

After steps shown in FIGS. 13A and 13B, an upper portion of the hard mask HM is anisotropically etched by the RIE method while using the photoresist PR as a mask. Accordingly, the upper portion of the end of the hard mask HM formed into a loop is removed. However, as shown in FIG. 18B, a lower portion of the end of the hard mask HM still remains.

Next, using oxygen plasmas obtained by discharging oxygen, the photoresist PR is isotropically etched. Accordingly, the photoresist PR is retracted without etching the hard mask HM as shown in FIGS. 19A and 19B. For example, the side surface of the photoresist PR is retracted from the position L_{PR} to a position L_{PR1} shown in FIG. 19A. Accordingly, a part of the upper surface of the hard mask HM is further exposed and the end regions of the line patterns of the word lines WL widen. In the second embodiment, there is no need to use gas having a relatively high oxygen content because it is unnecessary to incline the photoresist PR. Etching gas containing the same main components as those of the etching gas used to process the hard mask HM in the first embodiment can be used. For example, CF₄ gas can be used as the etching gas.

Next, as shown in FIG. 20A, using the photoresist PR as a mask, the hard mask HM in the end regions of the line patterns of the word lines WL is removed. Accordingly, a stepped portion 160 is formed on the end of the hard mask HM as shown in FIGS. 20A and 20B.

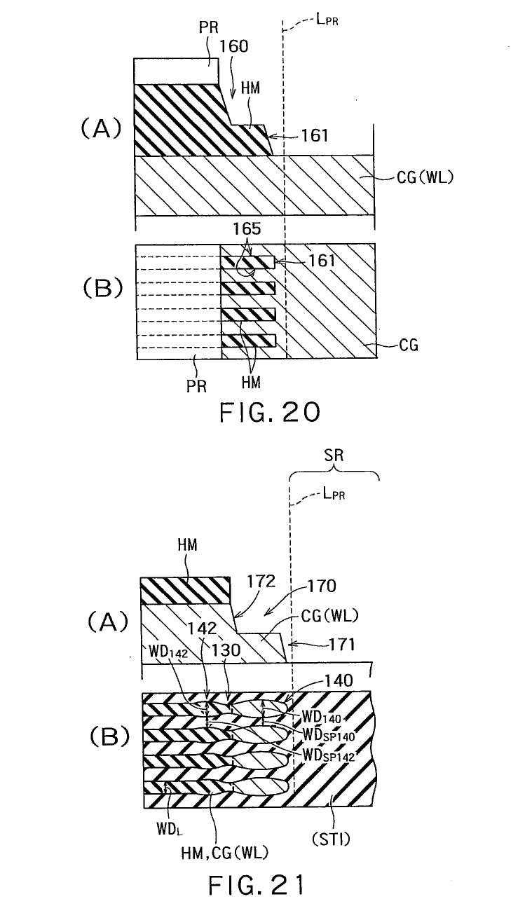

After removing the photoresist PR, the material of the word lines WL is then processed by the RIE method while using the hard mask HM as a mask. At the beginning of the etching, the hard mask HM including a lower stage of the stepped portion 160 functions as a mask. Therefore, the material of the word lines WL is initially processed according to the lower stage of the hard mask HM. At this time, the hard mask HM is also etched to some extent. Because the end and corners of the hard mask HM are easier to be etched, the lower stage of the stepped portion 160 is also etched from an end surface 161 and a side surface 165. Therefore, the lower stage of the stepped portion 160 is formed to be gradually elongated in the extension direction of the line patterns by the etching. Accordingly, the material of the word lines WL present under the lower stage of the stepped portion 160 is etched into an elongated shape although the etching residue adheres to the material. As a result, the line width WD₁₄₀ of the first wide portion 140 can be formed to be thin as compared with the conventional technique. Furthermore, the space width WD_{SP140} between the adjacent first wide portions 140 shown in FIG. 17 can be formed to be wide as compared with the conventional technique. An end surface 171 of each word line WL shown in FIG. 21A is tapered because the end surface 161 of the hard mask HM shown in FIG. 20A is also tapered and etched.

After the lower stage of the stepped portion 160 of the hard mask HM is removed by the etching, the remaining hard mask HM (an upper stage of the stepped portion 160) functions as a mask. Accordingly, the material of the word lines WL present under the lower stage of the stepped portion 160 is also etched, and the stepped portion 160 is transferred onto the material of the word lines WL as shown in FIG. 21A. At this time, the second wide portions 142 are formed. That is, when the word lines WL are processed using the upper stage of the stepped portion 160 of the hard mask HM as a mask, the end surface of the line pattern of each of the word lines WL is located at a position 172 shown in FIG. 21A. Therefore, the etching residue deposits on vicinities of the end surface 172 and the second wide portion 142 is formed. As a result, a stepped portion 170 is formed on each word line WL, the first wide portion 140 is formed on a lower stage of the stepped portion 170 of the word line WL, and the second wide portion 142 is formed on an upper stage of the stepped portion 170 of the word line WL.

In this way, according to the second embodiment, the end surface of each word line WL corresponds to the end surface 171 on the lower stage of the stepped portion 170 and corresponds to the end surface 172 on the upper stage of the stepped portion 170. The end surface 172 is located nearer the center side of the line pattern than the end surface 171. The etching residue deposits on vicinities of the end surface 171 on the lower stage of the stepped portion 170 and on the vicinities of the end surface 172 on the upper stage of the stepped portion 170. Therefore, as shown in FIG. 21B, the second wide portion 142 is formed nearer the center side of the line pattern than the first wide portion 140. The narrow portion 130 is formed between the first wide portion 140 and the second wide portion 142. That is, the first wide portion 140 is formed nearer the tip end of the line pattern of each word line WL than the narrow portion 130, and the second wide portion 142 is formed nearer the center side of the line pattern of each word line WL than the narrow portion 130.

In this way, the etching residue is dispersed in the first wide portion 140 and the second wide portion 142 and deposited in a wider range. Therefore, the first and second wide portions 140 and 142 are both thinner than the end of the conventional word line. Therefore, the space widths WD_{SP140} and WD_{SP142} can be both formed to be wide as compared with the conventional technique. As a result, similarly to the first embodiment, the second embodiment can keep the breakdown voltage between the adjacent word lines WL and suppress the short-circuit between the adjacent word lines WL.

According to the first and second embodiments, the end of the line pattern of each word line WL is formed to be narrow (thin) on purpose on the assumption of adhesion of the etching residue, and the process conversion difference from the hard mask HM to the line pattern of each word line WL is suppressed to be small. Furthermore, according to the second embodiment, the adhesion of the etching residue is dispersed by providing the stepped portion on the end of each word line WL, thereby suppressing the process conversion difference from the hard mask HM to the line pattern of each word line WL to be small. The first and second embodiments can thereby keep the breakdown voltage between the adjacent word lines WL and suppress the short-circuit between the adjacent word lines WL.

It is needless to mention that the above embodiments are applicable not only to line patterns of the word lines WL but also to line patterns of other conductors.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate; and
a plurality of line patterns formed into stripes provided above the semiconductor substrate, wherein
each of the line patterns includes a narrow portion having a constricted width in a perpendicular direction to an extension direction of the line pattern.

2. The device of claim 1, wherein the narrow portion is provided on an end of each of the line patterns.

3. The device of claim 1, wherein each of the line patterns includes a first wide portion wider than the narrow portion in a width in the perpendicular direction to the extension direction of the line pattern, the first wide portion being nearer a tip end of the line pattern than the narrow portion.

4. The device of claim 2, wherein each of the line patterns includes a first wide portion wider than the narrow portion in a width in the perpendicular direction to the extension direction of the line pattern, the first wide portion being nearer a tip end of the line pattern than the narrow portion.

5. The device of claim 3, wherein each of the line patterns includes a second wide portion wider than the narrow portion in a width in the perpendicular direction to the extension direction of the line pattern, the second wide portion being nearer a center side of the line pattern than the narrow portion.

6. The device of claim 4, wherein each of the line patterns includes a second wide portion wider than the narrow portion in a width in the perpendicular direction to the extension direction of the line pattern, the second wide portion being nearer a center side of the line pattern than the narrow portion.

7. The device of claim 1, wherein the line patterns are patterns of control gates of a NAND flash EEPROM.

8. A manufacturing method of a semiconductor device comprising:
forming a line-pattern material layer above a semiconductor substrate in order to form a plurality of line patterns above the semiconductor substrate;
forming a mask material on the line-pattern material layer;
processing the mask material into a shape of the line patterns;
processing an end of the mask material in such a manner that a taper or a stepped portion is provided on the end of the mask material; and
etching the line-pattern material layer using the mask material as a mask in order to process the line-pattern material layer into a shape of the line patterns, and in order to form a narrow portion having a constricted width in a perpendicular direction to an extension direction of the line patterns on ends of each line pattern.

9. The method of claim 8, wherein
the processing the end of the mask material comprises:
forming a photoresist covering regions other than the end region, the photoresist uncovering an end region of the mask material; and
processing the end of the mask material into a tapered shape by etching the mask material using the photoresist as a mask while retracting a side surface of the photoresist.

10. The method of claim 8, wherein
the processing the end of the mask material comprises:
forming a photoresist covering regions other than the end region, the photoresist uncovering an end region of the mask material;
etching an upper portion of the mask material in the end region while using the photoresist as a mask;
widening the end region by retracting a side surface of the photoresist; and
providing a stepped portion on the end of the mask material by etching the mask material in the end region while using the photoresist as a mask.

11. The method of claim 8, wherein at a time of etching the line-pattern material layer, an etching residue is deposited on a tip end of each of the line patterns rather than the narrow portion of the line patterns, thereby forming a first wide portion wider than the narrow portion in a width in the perpendicular direction to the extension direction of the line pattern nearer the tip end of the line pattern than the narrow portion.

12. The method of claim 11, wherein at a time of etching the line-pattern material layer, an etching residue is deposited on a center side of each of the line patterns rather than the narrow portion of the line patterns, thereby forming a second wide portion wider than the narrow portion in a width in the perpendicular direction to the extension direction of the line pattern nearer the center side of the line pattern than the narrow portion.

13. The method of claim 8, wherein the line patterns are patterns of control gates of a NAND flash EEPROM.

14. The method of claim 9, wherein the mask material is etched while retracting the side surface of the photoresist using etching gas containing oxygen.

15. The method of claim 14, wherein the side surface of the photoresist is retracted by using oxygen plasmas obtained by discharging oxygen.

16. The method of claim 10, wherein the side surface of the photoresist is retracted by using oxygen plasmas obtained by discharging oxygen.

17. The method of claim 9, wherein the mask material is etched while retracting the side surface of the photoresist using etching gas containing CxHyFz, where x, y, and z are positive numbers, and oxygen.

18. The method of claim 10, wherein the mask material is etched while retracting the side surface of the photoresist using etching gas containing CxHyFz, where x, y, and z are positive numbers, and oxygen.
